(19) United States
(12) Patent Application Publication
(10) Pub. No.: US 2023/0030762 A1
(43) Pub. Date: Feb. 2, 2023

(54) METHOD FOR FORMING TITANIUM NITRIDE FILM AND APPARATUS FOR FORMING TITANIUM NITRIDE FILM

(71) Applicant: Tokyo Electron Limited, Tokyo (JP)

(72) Inventors: Kensuke HIGUCHI, Nirasaki City (JP); Asaka FUJIKAWA, Nirasaki City (JP); Tsuyoshi TAKAHASHI, Nirasaki City (JP)

(21) Appl. No.: 17/812,523

(22) Filed: Jul. 14, 2022

(30) Foreign Application Priority Data
Jul. 27, 2021 (JP) 2021-122677

(51) Int. Cl. H01L 27/108; C23C 16/34; C23C 16/455; C23C 16/02

(52) U.S. Cl. CPC H01L 27/10876; C23C 16/34; C23C 16/45525; C23C 16/0236

(57) ABSTRACT

A method of forming a titanium nitride film on a substrate. The method includes: performing treatment of changing hydrophilicity of a base film formed on a substrate including a surface on which the base film capable of having its hydrophilicity changed is formed; and forming a titanium nitride film by vapor phase growth on a top surface of the base film subjected to the treatment of changing the hydrophilicity.

### CROSS-REFERENCE TO RELATED APPLICATION

This application is based upon and claims the benefit of priority from Japanese Patent Application No. 2021-122677, filed on Jul. 27, 2021, the entire contents of which are incorporated herein by reference.

### TECHNICAL FIELD

The present disclosure relates to a method for forming a titanium nitride film and an apparatus for forming a titanium nitride film.

### BACKGROUND

A titanium nitride (TiN) film is used for various purposes in manufacturing semiconductor devices. This TiN film is formed by using, for example, a raw material gas containing titanium (Ti) (e.g., titanium tetrachloride (TiCl₄) gas) as a film forming gas and a reaction gas containing nitrogen (N) (e.g., ammonia (NH₃) gas).

Patent Document 1 describes a technique for orienting a TiN film in (111) and (200) by adjusting a magnetic field to change plasma density when forming a TiN film through a magnetron sputtering method.

### PRIOR ART DOCUMENT

[Patent Document]
Patent Document 1: Japanese Laid-Open Patent Publication No. 8-250452

### SUMMARY

According to one embodiment of the present disclosure, there is provided a method of forming a titanium nitride film on a substrate. The method includes: performing treatment of changing hydrophilicity of a base film formed on a substrate including a surface on which the base film capable of having its hydrophilicity changed is formed; and forming a titanium nitride film by vapor phase growth on a top surface of the base film subjected to the treatment of changing the hydrophilicity.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIGS. 1A and 1B are schematic views illustrating a structure in which a TiN film is embedded in a recess.

FIG. 2 is a view illustrating a crystal structure of TiN.

FIG. 3 illustrates a TiN crystal viewed in a direction opposite to the (111) direction.

FIG. 4 illustrates a TiN crystal viewed in a direction opposite to the (200) direction.

FIG. 5 illustrates a TiN crystal viewed in a direction opposite to the (220) direction.

FIG. 6 is an explanatory view illustrating a flow of wafer processing according to the present disclosure.

FIG. 7 is a vertical cross-sectional side view of a hydrophilic adjustment apparatus.

FIG. 8 is a vertical cross-sectional side view of a film forming apparatus.

FIG. 9 is a view illustrating an example of a film forming sequence of a TiN film.

FIG. 10 is a plan view of a film forming system according to the present disclosure.

FIG. 11 is a graph showing a relationship between a peak intensity ratio of XRD and a void ratio.

FIG. 12 is a graph showing a relationship between a contact angle of a base film and a peak intensity ratio of XRD.

FIG. 13 is a diffraction spectrum diagram showing measurement results of XRD.

FIG. 14 is a table comparing the experimental results of the examples and the reference example.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

Before explaining the specific technical contents regarding a method for forming a titanium nitride (hereinafter, also referred to as “TiN”) film of the present disclosure, a configuration example of a device manufactured by using a TiN film and its problems will be described.

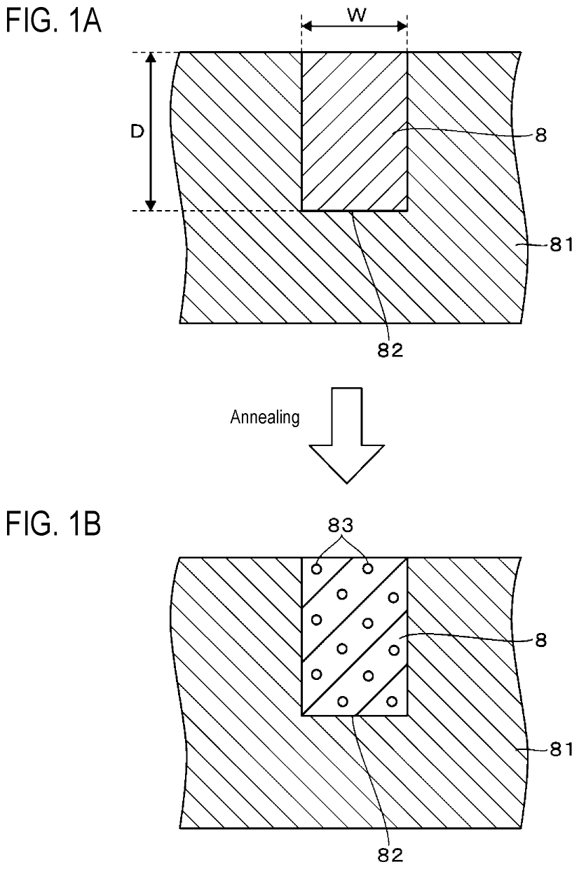

A TiN film formed through the method of the present disclosure forms, for example, a wiring layer which is a wordline of a dynamic random access memory (DRAM). For example, as illustrated in FIG. 1A, TiN 8 is embedded in a groove-shaped recess 82 formed in a silicon oxide (SiO) film 81 which is a base film formed on a surface side of a wafer. For example, the TiN film is formed through an atomic layer deposition (ALD) method which will be described later, and TiN having a polycrystalline structure grows inside the recess 82 while being deposited on each of the bottom and the inner surface of the side wall of the recess 82, so that embedding in the recess 82 progresses.

The SiO film 81 is used as an insulating film, and the recess 82 has a depth D of about 80 to 200 nm and an opening width W of about 10 to 20 nm, and the ratio of the depth D to the opening width W (D/W) is formed to a size of about 5 to 20.

In general, the recess 82 of a wordline has a smaller aspect ratio than a recess that forms a via hole, and thus the resistance value thereof may be lowered by embedding TiN compared with embedding tungsten which is used as a wiring material in the related arts.

In a DRAM manufacturing process, after forming a TiN film to be embedded in a recess 82, annealing is performed for heating the film at a temperature of about 750 to 1,000 degrees C. in an inert gas atmosphere for the purpose of diffusing impurities and the like. Meanwhile, small voids 83, which are small pores, may be formed in the TiN 8 embedded in the recess 82. It was also found that the voids 83 may be additionally formed by the annealing performed after the film formation (see FIG. 1B).

When a large number of voids 83 are generated in the TiN film used as the wiring layer in this way, a current flow is impaired, which causes the specific resistance of the TiN wiring layer to increase, which may adversely affect a device operation.

Here, it is presumed that the voids 83 formed by the annealing are generated since grains (crystal grains) in the TiN 8 grows by heating and thus minute gaps are produced between adjacent grains. In addition, it is presumed that, when a TiN film is formed by using a raw material gas containing impurities such as chlorine in TiCl₄, the impurities aggregate at unstable interfaces between grains, thereby promoting the formation of voids 83. According to this model, it can be expected that, when it is possible to increase the proportion of grains having stable interfaces, it will be possible to suppress the generation of voids 83.

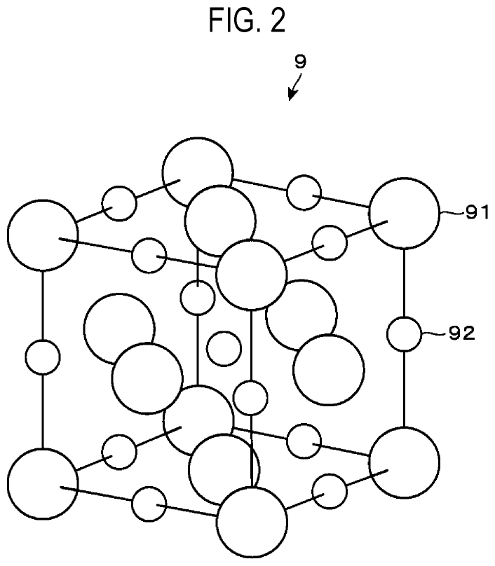

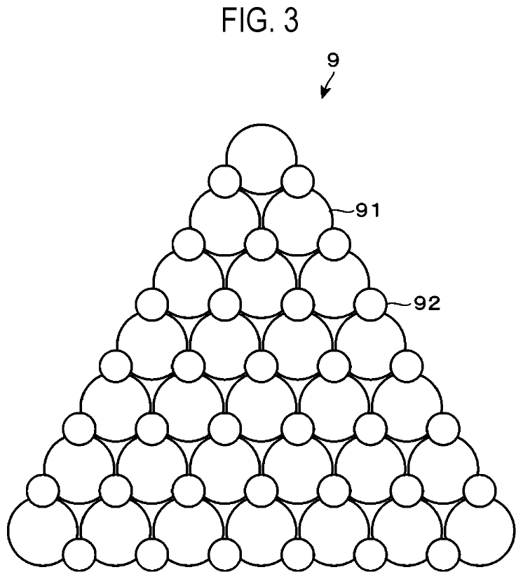

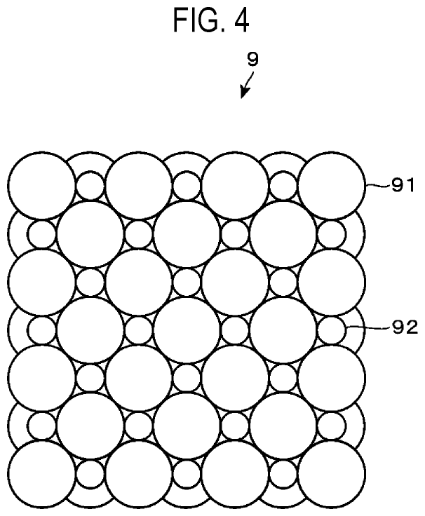

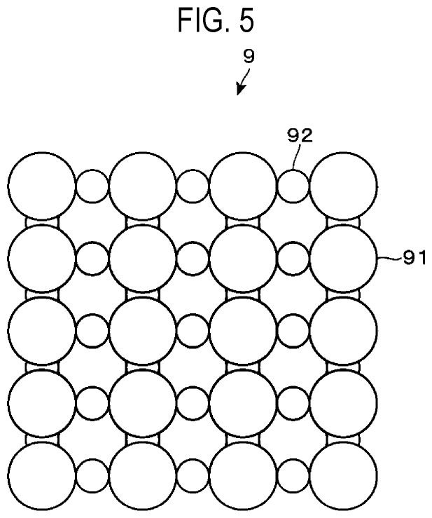

Regarding interface stability between grains, the inventors focused on the crystal structure of TiN. As illustrated in FIG. 2, a TiN crystal 9 containing two types of atoms of titanium 91 and nitrogen 92 has a face-centered cubic lattice structure. When expressed using Miller indices, this TiN has three types of crystal planes, i.e., a crystal plane growing in the (111) direction illustrated in FIG. 3, a crystal plane growing in the (200) direction illustrated in FIG. 4, and a crystal plane growing in the (220) direction illustrated in FIG. 5. The figures illustrated in FIGS. 3 to 5 schematically illustrate the crystal planes seen from the orientations facing respective crystal directions. For convenience, the crystal plane that grows in each of the above-mentioned crystal directions is also described as a “(111) crystal plane” or the like.

According to the molecular dynamics (MD) simulation performed by the inventors, it was found that interfaces of grains which are in contact with each other on the crystal planes in the (111) direction and the (220) direction (hereinafter, also referred to as “(111)(220) interfaces”) have a relatively small number of dangling bonds (unbonded hands) (a relatively large number of atomic bonds between interfaces). Meanwhile, it was found that interfaces of grains which are in contact with each other on the crystal planes in the (111) direction and the (200) direction (hereinafter, also referred to as “(111)/(200) interfaces”), and interfaces of grains which are in contact with each other in the (220) direction and the (200) direction (hereinafter, also referred to as “(220)/(200) interfaces”) have a relatively large number of dangling bonds (a relatively small number of atomic bonds between the interfaces).

According to the results of the above-mentioned preliminary simulation, it was found that (111)/(200) interfaces and (220)/(200) interfaces are more unstable than (111)/(220) interfaces. Impurities such as Cl tend to aggregate at unstable (111)/(200) interfaces and (220)/(200) interfaces, which have many dangling bonds. It is expected that this may cause the formation of voids 83.

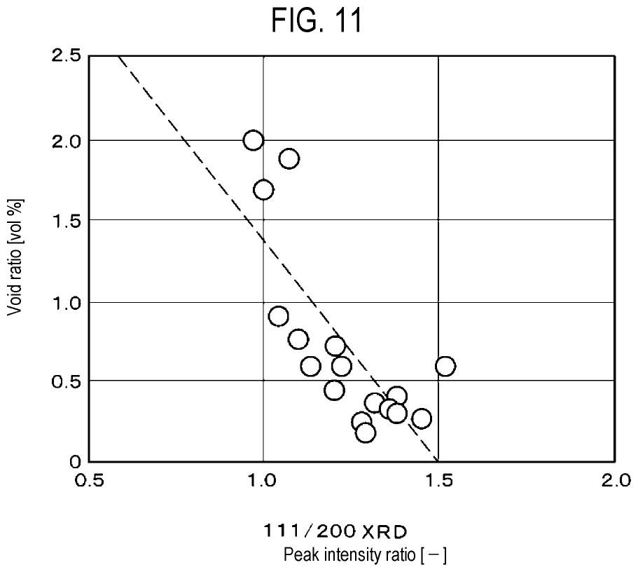

In other words, in the TiN 8, when it is possible to increase the ratio of (111)/(220) interfaces and to decrease the ratio of the (200) interfaces, it is possible to suppress the formation of voids 83. That is, it is possible to suppress the formation of voids 83 by increasing the number of grains having the (111) and (220) planes and decreasing the number of grains having the (200) planes. This is also supported by the results of a preliminary experiments to be described below, in which the results will be described with reference to FIG. 11.

The inventors focused on the hydrophilicity of a base film (the SiO film 81 in the example of FIGS. 1A and 1B) as a method for controlling the interfaces of TiN grains in TiN 8. That is, it was newly found that it is possible to control the crystal structure of the interfaces in the TiN 8 by changing the hydrophilicity of the base film. For example, it is possible to control the hydrophilicity of a SiO film 81 by changing the chemical species to be bonded to unbonded hands on the surface.

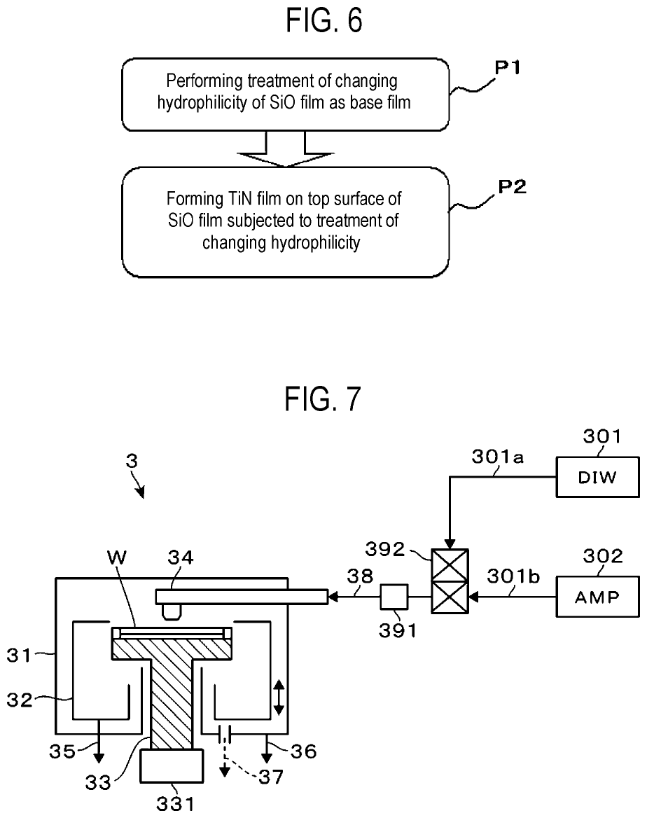

In the method for forming a TiN film according to the present disclosure, as illustrated in FIG. 6, treatment of changing the hydrophilicity of the SiO film 81 as a base film is performed (step P1), and then a TiN film is formed on the top surface of the SiO film 81 that has been subjected to the corresponding process (step P2). The process in step P1 may be hydrophilic treatment for improving the hydrophilicity of the SiO film 81, or hydrophobic treatment for reducing the hydrophilicity of the SiO film 81.

At this time, as shown in the experimental results to be described later, it was found that, when the hydrophilic treatment is performed on the SiO film 81, it is possible to reduce grains having the (200) plane, which is a factor of forming voids 83.

Therefore, a method of suppressing the formation of voids in a TiN film by performing hydrophilic treatment on a base film will be described below with reference to FIGS. 7 to 9.

FIG. 7 shows an example of a configuration of a hydrophilicity adjustment apparatus 3 that performs hydrophilic treatment on a wafer W having a SiO film 81 formed thereon. The hydrophilicity adjustment apparatus 3 is configured as a single-wafer type liquid processing apparatus that performs hydrophilic treatment of a SiO film 81 by supplying a known ammonia-hydrogen peroxide mixture (APM) liquid to a wafer W having a SiO film 81 formed on the surface thereof.

The hydrophilicity adjustment apparatus 3 includes: an outer chamber 31 that defines a closed processing space in which each of the processes, such as liquid processing for supplying an APM liquid to a wafer W, rinse cleaning with deionized water (DIW), and shake-off drying, is performed; a wafer holding mechanism 33 that is provided in the outer chamber 31 and rotates the wafer while holding the wafer W substantially horizontally; a nozzle arm 34 that supplies a processing liquid to the top surface side of the wafer W held by the wafer holding mechanism 33; and an inner cup 32 that provided within the outer chamber 31 so as to surround the wafer holding mechanism 33 and receives the processing liquid scattered from the rotating wafer W to the periphery of the rotating wafer W.

A drainage line 36 for discharging drainage of DIW or the like and an exhaust line 37 for exhausting the atmosphere in the outer chamber 31 are connected to the bottom surface of the outer chamber 31. The side wall surface of the outer chamber 31 is provided with a carry-in/out port (not illustrated) which is opened/closed by a gate valve (not illustrated) to carry in/out a wafer W.

The wafer holding mechanism 33 includes a disk-shaped stage that holds a wafer W horizontally, and a rotation shaft that is connected to a central portion on the bottom surface side of the stage. A rotation driver 331 for rotating the wafer holding mechanism 33 is provided at the lower end of a rotation driving shaft.

The nozzle arm 34 is provided with a nozzle for supplying a processing liquid at the tip portion thereof, and is capable of moving the nozzle between a position above the central portion of a wafer W held by the wafer holding mechanism 33 and a standby position provided in a region outside, for example, the inner cup 32 by a driving mechanism (not illustrated).

The inner cup 32 is configured to move up and down between a processing position surrounding a wafer W held by the wafer holding mechanism 33 and a retracted position retracted downward from the processing position by a lifting mechanism (not illustrated). The inner cup 32 serves to receive a processing liquid scattered from the surface of a rotating wafer W at the processing position and discharge the processing liquid to the exterior through the drainage line 35 connected to the bottom side thereof.

Next, a mechanism for supplying a processing liquid to the nozzle arm 34 will be described. The nozzle provided on the nozzle arm 34 is connected to a processing liquid supply line 38, and the processing liquid supply line 38 is branched into a DIW supply line 301a and an APM supply line 301b via a switching valve 392.

An APM supplier 302 is connected to the upstream side of the APM supply line 301b, and an AMP, which is a processing liquid for hydrophilizing the SiO film 81 on the surface of a wafer W and is a mixture of ammonia and hydrogen peroxide solution, is supplied from the APM supplier 302.

The DIW supply line 301a on the other side branched from the processing liquid supply line 38 is provided with a DIW supplier 301 for supplying DIW, which is a processing liquid for rinsing and cleaning the APM liquid remaining on the wafer W after hydrophilic treatment.

A flow rate adjuster 391 is interposed in the processing liquid supply line 38, so that it is possible to adjust the supply flow rate of the APM liquid supplied from the APM supplier 302 and the DIW supplied from the DIW supplier 301.

Next, an example of a configuration of a film forming apparatus 4 for forming a TiN film through an ALD method, which is a vapor phase growth method, on the top surface side of the SiO film 81 subjected to the hydrophilic treatment will be described.

The film forming apparatus 4 is provided with a processing container 40 for accommodating a wafer W and performing a film forming process in a vacuum atmosphere, and the side surface of the processing container 40 is provided with a carry-in/out port 41 configured to be openable/closable by a gate valve 29.

For example, an annular exhaust duct 43 is arranged in an upper portion of the side wall of the processing container 40. On the top surface of the exhaust duct 43, a ceiling plate 44 is installed so as to close the upper opening of the processing container 40. The processing container 40 is connected to a vacuum exhauster 46 including, for example, a vacuum pump, via a vacuum exhaust path 45 connected to the exhaust port 431 of the exhaust duct 43. An auto pressure controller (APC) valve 47 for adjusting the pressure in the processing container 40 is interposed in the vacuum exhaust path 45.

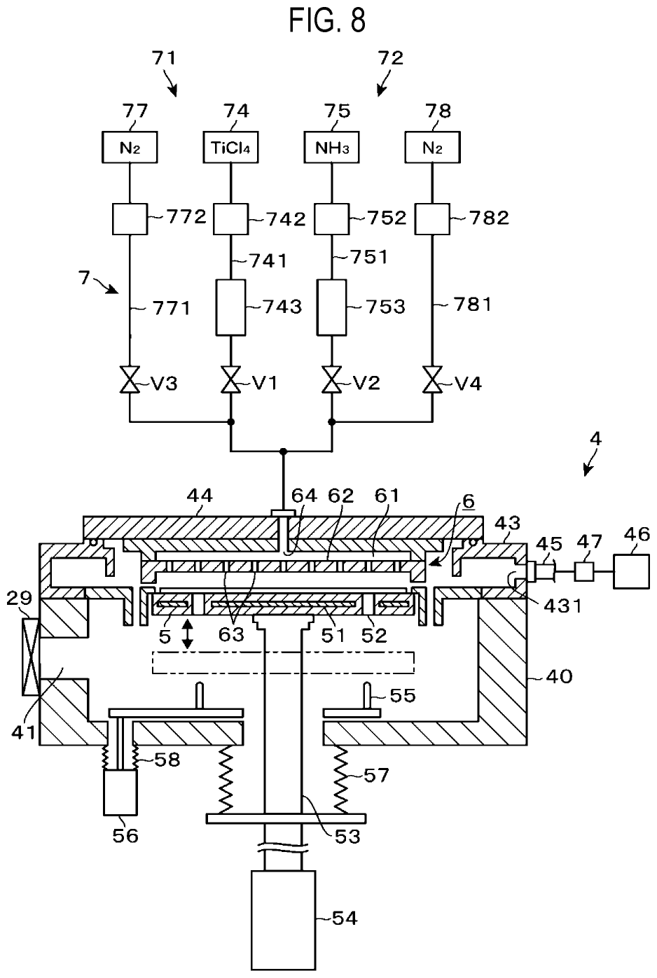

Inside the processing container 40, a stage 5 that supports a wafer W horizontally is provided. A heater 51 for heating the wafer W is embedded in the stage 5. The stage 5 is configured to be vertically movable up and down by the lifting mechanism 54. In FIG. 8, the stage 5 moved to a wafer W delivery position is indicated by an alternate long and short dash line. In the figure, reference numeral 55 indicates support pins for delivery of a wafer W, and the support pin is configured to be movable up and down by a lifting mechanism 56. Reference numeral 52 indicates through holes for the support pins 55, and reference numerals 57 and 58 indicate bellows which expand and contract in accordance with the elevating operation and lowering operation of the stage 5 and the support pins 55.

The processing container 40 is provided with a shower head 6 for supplying a processing gas into the processing container 40 so as to face the stage 5. The shower head 6 is provided therein with a gas diffusion space 61, and the bottom surface thereof is configured as a shower plate 62 in which a large number of gas ejection holes 63 are formed. A gas supply system 7 is connected to the gas diffusion space 61 via a gas introduction hole 64.

The gas supply system 7 includes a raw material gas supplier 71 for supplying a raw material gas and a reaction gas supplier 72 for supplying a reaction gas to the processing container 40.

The raw material gas is a gas containing a titanium compound including chlorine (Cl) and titanium (Ti), and as the titanium compound, for example, titanium tetrachloride (TiCl₄) is used. The reaction gas is a gas containing nitrogen (N) and reacting with the titanium compound to form titanium nitride (TiN), and as the nitrogen compound, for example, ammonia (NH₃) is used.

The raw material gas supplier 71 includes a TiCl₄ gas source 74 and a TiCl₄ gas supply path 741 for supplying a raw material gas. For example, a flow rate adjuster 742, a storage tank 743, and a valve V1 are installed in the TiCl₄ gas supply path 741 from the upstream side. The reaction gas supplier 72 includes an NH₃ gas source 75 and an NH₃ gas supply path 751 for supplying a reaction gas. For example, a flow rate adjuster 752, a storage tank 753, and a valve V2 are installed in the NH₃ gas supply path 751 from the upstream side.

These TiCl₄ gas and NH₃ gas are temporarily stored in the storage tanks 743 and 753, respectively, pressurized to a predetermined pressure, and then supplied into the processing container 40. The supply and stop of respective gases from the storage tanks 743 and 753 to the processing container 40 are performed by opening and closing the valves V1 and V2.

In addition, the gas supply system 7 includes an inert gas supplier that supplies an inert gas to the processing container 40, and for example, nitrogen (N₂) gas is used as an inert gas. The inert gas supplier in this example includes N₂ gas sources 77 and 78 and N₂ gas supply paths 771 and 781.

In this example, the N₂ gas supplied from the N₂ gas source 77 of the raw material gas supplier 71 is a purge gas for the TiCl₄ gas. The N₂ gas source 77 is connected to the downstream side of the valve V1 provided in the TiCl₄ gas supply path 741 described above via the N₂ gas supply path 771. In addition, the N₂ gas supplied from the N₂ gas source 78 of the reaction gas supplier 72 is a purge gas for NH₃ gas. The N₂ gas source 78 is connected to the downstream side of the valve V2 provided in the NH₃ gas supply path 751 described above via the N₂ gas supply path 781.

In FIG. 8, reference numerals 772 and 782 indicate flow rate adjusters, respectively, and reference numerals V3 and V4 indicate valves, respectively.

The operation of processing a wafer W by using the hydrophilicity adjustment apparatus 3 and the film forming apparatus 4 having the above-described configurations will be described. First, a wafer W is transported to the hydrophilicity adjustment apparatus 3, and hydrophilic treatment for a SiO film 81 is performed. That is, when the wafer W is delivered to the wafer holding mechanism 33, the nozzle of the nozzle arm 34 moves to a position above the central portion of the wafer W. Thereafter, the wafer W is rotated by the wafer holding mechanism 33, and the supply of the APM liquid from the nozzle is started. The APM liquid supplied to the wafer W spreads over the entire surface of the wafer W due to the influence of centrifugal force.

The APM liquid has an action of terminating a dangling bond on the surface of the SiO film 81 with a hydroxy group (OH group). The hydroxy group thus formed on the surface of the SiO film 81 (wafer W) improves the hydrophilicity of the wafer W (step P1). The processing liquid having the effect of hydrophilizing the SiO film 81 is not limited to the APM liquid, and a hydrochloric hydrogen peroxide mixture (HPM) may also be used.

After supplying the APM liquid for a predetermined length of time, the processing liquid supplied to the wafer W is switched to DIW, and rinse cleaning is performed. Thereafter, the supply of the DIW is stopped while the rotation of the wafer W is continued, the remaining processing liquid is shaken off to dry the wafer W, and the hydrophilic treatment is completed.

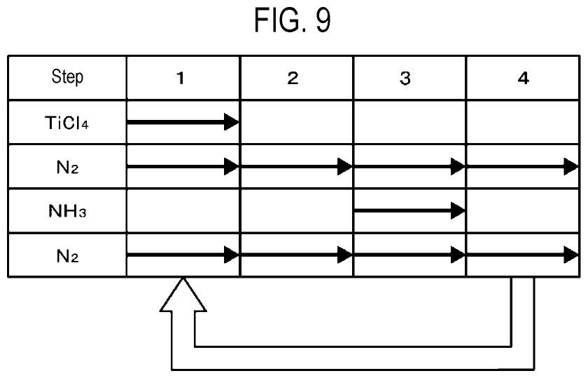

The wafer W after the hydrophilic treatment is taken out from the hydrophilicity adjustment apparatus 3 and carried into the film forming apparatus 4. In the film forming apparatus 4, a TiN film is formed through an ALD method (step P2). The gas supply sequence illustrated in FIG. 9 shows the supply timing of TiCl₄ gas, NH₃ gas, and N₂ gas used for film formation to the processing container 40. In FIG. 9, N₂ below TiCl₄ indicates N₂ gas supplied from the N₂ gas source 77, and N₂ below NH₃ indicates N₂ gas supplied from the N₂ gas source 78.

The wafer W carried into the processing container 40 is placed on the stage 5, the heating of the wafer W by the heater 51 is started, and N₂ gas is supplied from each of the N₂ gas sources 77 and 78 into the processing container 40 at a preset flow rate. Then, evacuation of the interior of the processing container 40 is performed by the vacuum exhauster 46, and the opening degree of the APC valve 47 is adjusted such that the interior of the processing container 40 reaches a target pressure.

Subsequently, a step of forming a TiN film is carried out based on the gas supply sequence of FIG. 9. This step includes steps S1 to S4 illustrated in FIG. 9.

First, the TiCl₄ gas, which is a raw material gas, is supplied by opening the valve V1, and the N₂ gas is supplied from each of the N₂ gas sources 77 and 78 at a preset flow rate (step S1). By this process, TiCl₄, which is a component containing Ti, is adsorbed on the entire surface of the wafer W.

Next, the valve V1 is closed to stop the supply of TiCl₄ gas, while the supply of N₂ gas from the N₂ gas sources 77 and 78 is continued. In this way, purging with N₂ gas is performed to remove the TiCl₄ gas remaining in the processing container 40 (step S2).

Next, while the supply of N₂ gas from the N₂ gas sources 77 and 78 is continued, NH₃ gas which is a reaction gas is supplied by opening the valve V2. By this process, TiCl₄ adsorbed on the wafer W and NH₃ react with each other to form a thin film of TiN (step S3).

Subsequently, while the valve V2 is closed to stop the supply of NH₃ gas, the supply of N₂ gas from the N₂ gas sources 77 and 78 is continued to perform purging with N₂ gas, thereby removing the NH₃ gas remaining in the processing container 40 (step S4).

In this way, in the step of forming the TiN film, the raw material gas and the reaction gas are alternately supplied while supplying the N₂ gas, which is an inert gas, into the processing container 40, and steps S1 to S4 are repeatedly performed a set number of times to form a TiN film of a desired thickness.

After the formation of the TiN film is completed, the wafer W is carried out from the film forming apparatus 4. In the subsequent stage, an etching treatment is performed on the TiN film formed on the top surface of the SiO film 81 to remove an unnecessary portion, and a structure in which TiN 8 is embedded in the recess 82 is obtained (see FIG. 1A).

In the film forming method according to the present disclosure, the SiO film 81 formed on the surface of the wafer W is subjected to hydrophilic treatment as an example of treatment of changing hydrophilicity, and then a TiN film is formed. As a result, as shown in the experimental results which will be described later, it is possible to suppress the formation of voids 83 in the TiN 8 when the wafer W is annealed.

Here, the content of the hydrophilic treatment is not limited to the case of the liquid processing with the APM liquid described with reference to FIG. 7. For example, as shown in the experimental results which will be described later, hydrophilic treatment for the base film of the TiN film may be performed by dry etching using an etching gas. Examples of the etching gas may be a mixed gas of nitrogen trifluoride (NF₃) gas, which is a fluorine-containing gas, and a nitrogen gas, and a mixed gas of hydrogen gas and nitrogen gas.

In the case of performing the hydrophilic treatment by dry etching, a case may be exemplified that a hydrophilic adjustment apparatus configured to perform dry etching by using a plasmatized and activated etching gas is provided instead of a hydrophilic adjustment apparatus 3 which performs hydrophilic treatment by liquid processing described above with reference to

In this case, for example, for a processing module (the film forming apparatus 4) having the configuration shown in FIG. 8, a case may be exemplified that an etching gas is configured by supplying an etching gas from the gas supply system 7 instead of a raw material gas and a reaction gas for forming a TiN film. In addition, a parallel flat plate type plasma module using capacitive coupling may be configured by grounding one of the shower head 6 and the stage 5 disposed to face each other in the etching apparatus and connecting a radio-frequency power supply for plasmatization to the other of the shower head 6 and the stage 5. In addition to this, as a plasma forming method, a configuration in which plasma is generated by using an inductively coupled antenna may be adopted, or a configuration in which microwaves are supplied from a microwave antenna to a processing gas to generate plasma may be adopted. The inductively coupled antenna or the microwave antenna is disposed, for example, on the top surface side of the shower head 6.

Further, in both the processing modules constituting the above-described etching apparatus and film forming apparatus 4, a wafer W is processed in a vacuum atmosphere. Therefore, by connecting these processing modules to a common vacuum transport chamber, it is possible to carry out a series of steps P1 and P2 illustrated in FIG. 6 in a common apparatus.

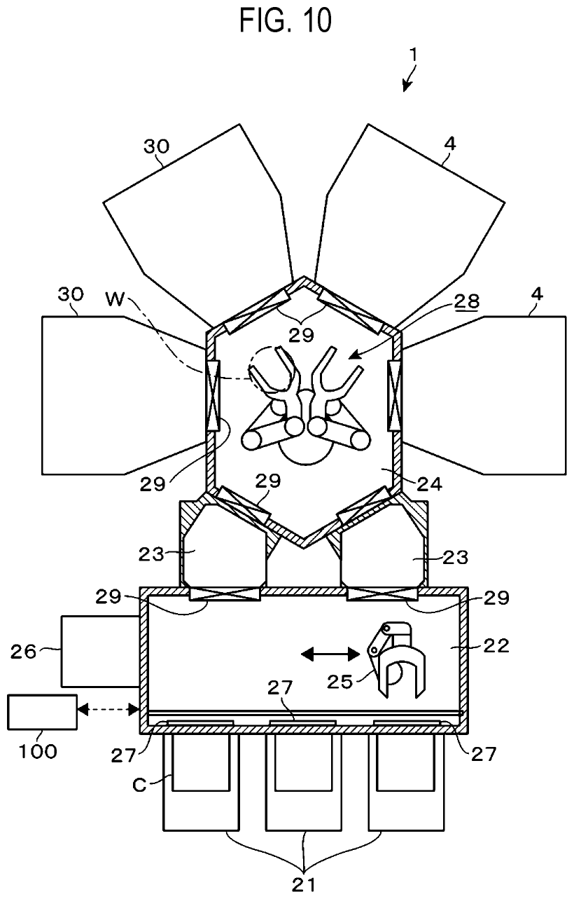

The film forming system 1 illustrated in FIG. 10 is configured as a multi-chamber system including etching apparatuses 30 and film forming apparatuses 4 which have been described above as processing modules. In the film forming system 1 illustrated in FIG. 10, a carrier C accommodating wafers W to be processed is transported to a load port 21 of the film forming system 1. The wafers W are taken out from the carrier C by a transport arm 25 and carried into an alignment chamber 26 via a normal pressure transport chamber 22. After being aligned in the alignment chamber 26, the wafers W are carried into the vacuum transport chamber 24 via load-lock chambers 23.

Subsequently, the wafers W are carried into the etching apparatuses 30 by transport arms 28 and subjected to hydrophilic treatment for the base films thereof by the above-described dry etching (step P1), and then the wafers W are carried into the film forming apparatus 4 to form a TiN film on the top surface side of each of the base films subjected to the hydrophilic treatment (step P2).

The film forming system 1 illustrated in FIG. 8 corresponds to an apparatus for forming a titanium nitride film on a substrate according to the present disclosure, the etching apparatuses 30 correspond to the hydrophilicity adjuster, and the film forming apparatuses 4 correspond to the film forming unit.

Here, in the film formation of a TiN film, the raw material gas containing Ti supplied to the wafers W is not limited to TiCl₄ gas. The raw material gas may be, for example, titanium tetrabromide (TiBr₄) or titanium tetraiodide (TiI₄). In addition, the raw material gas may be an organic raw material gas such as tetrakisdimethylaminotitanium (TDMAT). In addition, in order to improve the film quality of the TiN film to be formed, a Si-containing gas such as SiH₄ or SiH₂Cl₂ may be added to the raw material gas.

Furthermore, it is possible to improve hydrophilicity by performing hydrophilic treatment, and the base film (insulating film) formed on the bottom surface side of the TiN film is not limited to a SiO film 81. For example, the base film may be a SiN film, an alumina film, a polysilicon film, or an amorphous silicon film.

The vapor phase growth method of a TiN film to which the method of the present disclosure is applicable is not limited to the ALD method. The vapor phase growth method may be chemical vapor deposition (CVD) in which a raw material gas and a reaction gas are continuously supplied. Even in this case, by forming a TiN film after performing the hydrophilic treatment on the base film, it is possible to obtain a TiN film in which voids 83 are less likely to be formed compared with the case in which the hydrophilic treatment is not performed.

Furthermore, regarding the configuration of the apparatus for performing liquid processing, in addition to the single-wafer type described above with reference to FIG. 7, a batch-type liquid processing apparatus in which a large number of wafers W are immersed in a water tank storing an APM liquid may be used to perform liquid processing. Regarding the configuration of an apparatus for forming a TiN film, a batch-type film forming apparatus in which a boat holding a large number of wafers W is accommodated in a heating furnace and a film forming process is performed may be used. Alternatively, a semi-batch type film forming apparatus in which wafers W are disposed on a rotary table, and the wafers W are revolved around a rotation axis to pass through processing spaces partitioned from each other, thereby repeatedly performing adsorption of a raw material gas and film formation of a TiN thin film by a reaction gas may be used.

In each of the above-described embodiments, regarding treatment of changing the hydrophilicity of a base film illustrated in FIG. 6 (step P1), an application example in which hydrophilic treatment for improving the hydrophilicity of the base film is carried out has been described.

Meanwhile, as described above, the process carried out in step P1 may be hydrophobic treatment for reducing hydrophilicity. The inventors found that, when hydrophobic treatment is performed on the base film (e.g., the above-described SiO film 81) in step P1 and then a TiN film is formed on the top surface of the base film in step P2, the amount of impurities (chlorine, oxygen, silicon, and the like) in the TiN film may be increased or the roughness of the TiN film may be decreased. A TiN film having a low roughness may reduce wiring resistance when used as a barrier film in, for example, a TiN/W laminated structure.

For example, in the case of performing hydrophobic treatment by liquid processing, the case of using N-(trimethylsilyl) dimethylamine (TMSDMA) as a processing liquid may be exemplified. The TMSDMA is one of silylating agents having an action of terminating a dangling bond on the surface of a base film with a silyl group including silicon and a hydrocarbon.

The embodiments disclosed herein should be considered to be exemplary in all respects and not restrictive. The above-described embodiments may be omitted, replaced, or modified in various forms without departing from the scope and gist of the appended claims.

### EXAMPLES

### (Experiment 1)

As a preliminary experiment, the change in the content of voids 83 in a TiN film when the content ratio of crystal planes grown in each of the directions (111) and (200) was changed was investigated.

### A. Experimental Conditions:

A SiO film 81 was formed on the surface of a flat wafer W, and TiN films, having different content ratios of the above-described crystal planes, were formed by changing the gas flow rate and gas supply time when forming the TiN films on the SiO film. Thereafter, the wafer W was annealed at 750 degrees C. under an inert gas atmosphere, and then the content ratios of voids 83 (void ratios [vol %]) in the TiN films were obtained. The content of each crystal plane was obtained from the peak intensity in each crystal direction by an X-ray diffraction method (XRD). The void ratios were obtained by image analysis of transmission electron microscope (TEM) images.

### B. Experimental Results

FIG. 11 shows experimental results. The horizontal axis of FIG. 11 represents a peak intensity ratio in each of the (111) and (200) directions in the results of XRD analysis. According to the results of FIG. 11, the smaller the ratio of crystal planes grown in the (111) direction, the larger the void ratio tends to be. In contrast, as the ratio of crystal planes increases, the void ratio decreases. Therefore, it can be said that it is possible to suppress the formation of voids 83 by reducing the interfaces of unstable (200) crystal planes and increasing the interfaces of stable (111) crystal planes in the grains constituting a TiN film.

### (Experiment 2)

The effect of hydrophilic treatment on the crystal plane ratio of grains in a TiN film was investigated.

### A. Experimental Conditions

### Example 1

Hydrophilic treatment using an APM liquid was performed on wafers W each having a base film of a SiO film 81 formed on the surface thereof, and then a TiN film was formed through the ALD method described with reference to FIGS. 8 and 9. The contact angle of the SiO films 81 after the hydrophilic treatment was measured by using a contact angle meter. In addition, XRD analysis was performed on the formed TiN film.

### Example 2

A SiO film 81 and a TiN film were analyzed by the same method as in Example 1 except that a mixed gas of NF₃ gas and N₂ gas was used as an etching gas and hydrophilic treatment was performed by plasma etching.

### Example 3

A SiO film 81 and a TiN film were analyzed by the same method as in Example 1 except that a mixed gas of H₂ gas and N₂ gas was used as an etching gas and hydrophilic treatment was performed by plasma etching.

### Example 4

A SiO film 81 and a TiN film were analyzed by the same method as in Example 1 except that liquid processing was performed by using TMSDMA, which is a processing liquid (a silylating agent) for hydrophobizing the surface of the SiO film 81.

### Reference Example

A SiO film 81 and a TiN film were analyzed by the same method as in Example 1 except that the SiO film 81 was not hydrophilized.

### B. Experimental Results

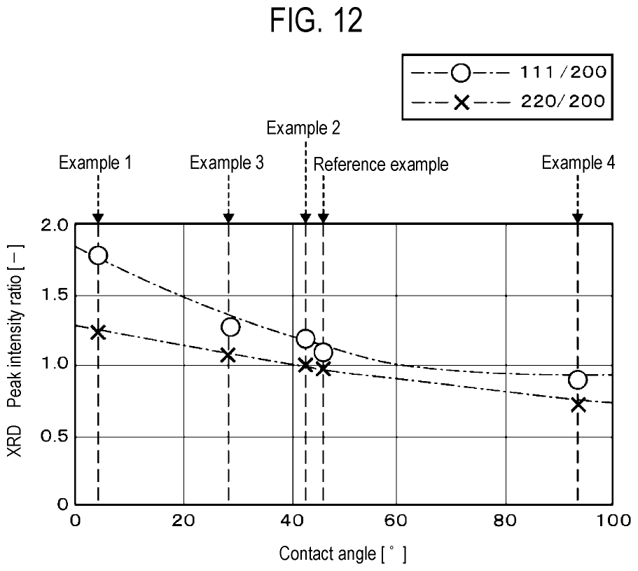

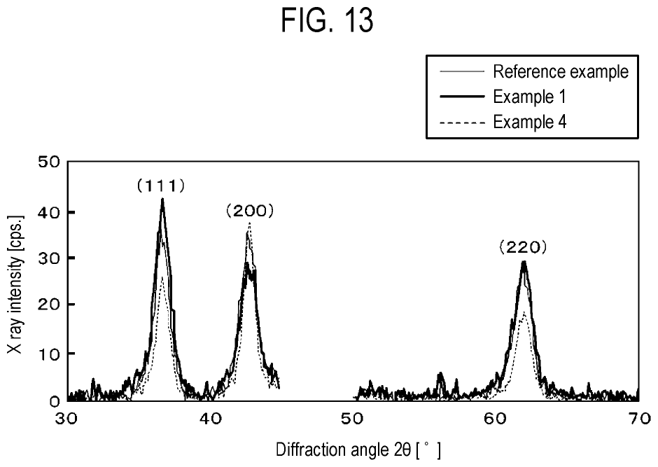

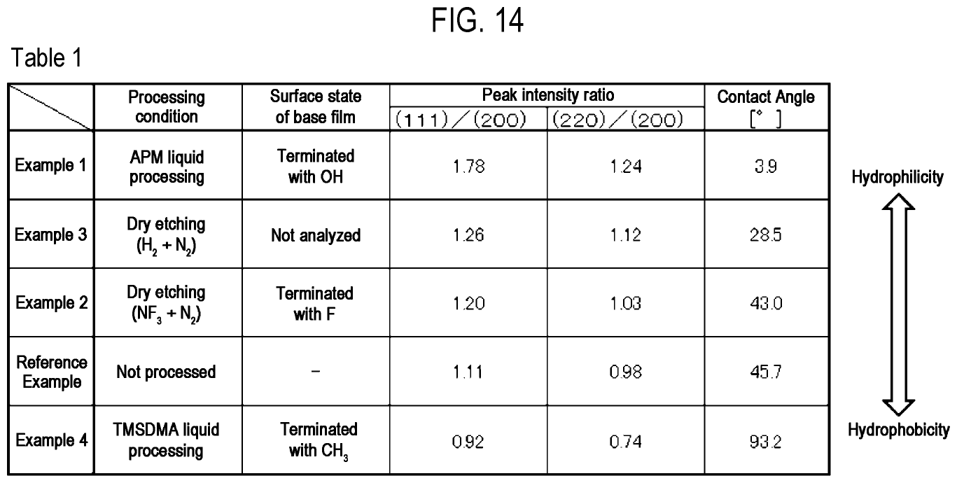

The results of each example and reference example are shown in FIG. 12 and Table 1 of FIG. 14. In addition, XRD spectra according to Examples 1 and 4 and Reference Example are shown in FIG. 13. The horizontal axis of FIG. 12 represent a contact angle of each SiO film 81, and the vertical axis represents each of peak intensity ratios of (111)/(200) and (220)/(200) in the results of XRD analysis of each TiN film. In addition to the peak intensity ratios and contact angle values, Table 1 of FIG. 14 also shows the surface states of base films after hydrophilic treatment/hydrophobic treatment (terminated state of dangling bonds). In Table 1 of FIG. 14, respective examples and the like are arranged in the ascending order of contact angles from the top to the bottom. The horizontal axis of FIG. 13 represents a diffraction angle 20, and the vertical axis represents a detected X-ray intensity.

According to the results shown in FIGS. 12 and Table 1 of FIG. 14, as the contact angle of a SiO film 81 increases due to the hydrophilic treatment, the ratio of crystal planes growing in each of the (111) and (220) directions to crystal planes growing in the (200) direction increases. As a result, it can be said that it is possible to reduce the interfaces of the unstable (200) crystal planes in grains constituting a TiN film. In contrast, in Example 4 in which the SiO film 81 subjected to hydrophobic treatment, the ratio of crystal planes growing in each of the (111) and (220) directions decreases compared with the reference example in which the hydrophobized process was not performed. This indicates that it is possible to increase the amount of impurities in a TiN film and form a TiN film with low roughness as described above, and may be used for the purpose of lowering the wiring resistance in a TiN/W laminated structure.

The contrast between Example 1 and Example 4 described above is clearly shown in the XRD spectra of FIG. 13, and the peak intensity in the (111) direction is larger in Example 1 than in Example 4. In contrast, the peak intensity in the (200) direction is smaller in Example 1 than in Example 4. It is unclear why the ratio of stable (111) crystal planes increases as the hydrophilicity of the SiO film 81 increases (the contact angle decreases). However, it was confirmed that hydrophilic treatment is an effective operation method in controlling a crystal structure of a TiN film formed on a base film (the SiO film 81).

According to the present disclosure, it is possible to control the characteristics of a titanium nitride film formed on a base film that is capable of having its hydrophilicity changed.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A method of forming a titanium nitride film on a substrate, the method comprising:
performing treatment of changing hydrophilicity of a base film formed on a substrate including a surface on which the base film capable of having its hydrophilicity changed is formed; and
forming a titanium nitride film by vapor phase growth on a top surface of the base film subjected to the treatment of changing the hydrophilicity.

2. The method of claim 1, wherein the treatment of changing the hydrophilicity is hydrophilic treatment that improves the hydrophilicity of the base film.

3. The method of claim 2, wherein the hydrophilic treatment is treatment of terminating an element on the surface of the base film with a hydroxy group.

4. The method of claim 3, wherein the hydrophilic treatment is liquid processing performed on the surface of the substrate by using an ammonia-hydrogen peroxide mixture (APM) liquid.

5. The method of claim 4, wherein, in the forming the titanium nitride film, a process of supplying a raw material gas containing a component containing titanium to the substrate so that the component is adsorbed on the surface of the substrate and then a process of supplying a reaction gas for nitriding the component to the substrate so that a thin film of titanium nitride is formed on the surface of the substrate are repeatedly executed.

6. The method of claim 5, wherein the base film is a silicon oxide film.

7. The method of claim 2, wherein the hydrophilic treatment is dry etching performed on the surface of the substrate by using an etching gas containing a fluorine-containing gas or hydrogen.

8. The method of claim 1, wherein the treatment of changing the hydrophilicity is hydrophobic treatment that reduces the hydrophilicity of the base film.

9. The method of claim 8, wherein the hydrophobic treatment is treatment of terminating an element of the surface of the base film with a silyl group.

10. The method of claim 9, wherein the hydrophobic treatment is liquid processing performed on the surface of the substrate by using N-(trimethylsilyl)dimethylamine (TMSDMA).

11. The method of claim 1, wherein, in the forming the titanium nitride film, a process of supplying a raw material gas containing a component containing titanium to the substrate so that the component is adsorbed on the surface of the substrate and then a process of supplying a reaction gas for nitriding the component to the substrate so that a thin film of titanium nitride is formed on the surface of the substrate are repeatedly executed.

12. The method of claim 1, wherein the base film is a silicon oxide film.

13. An apparatus of forming a titanium nitride film on a substrate, the apparatus comprising:
a hydrophilicity adjuster configured to perform treatment of changing hydrophilicity of a base film formed on a substrate including a surface on which the base film capable of having its hydrophilicity changed is formed; and
a film forming unit that forms a titanium nitride film by vapor phase growth on a top surface of the base film subjected to the treatment of changing the hydrophilicity.
